(19) United States
(12) Patent Application Publication
(10) Pub. No.: US 2026/0255518 A1
(43) Pub. Date: Aug. 27, 2026

(54) TILING-TYPE DISPLAY DEVICE

(71) Applicant: Samsung Electronics Co., Ltd., Suwon-si (KR)

(72) Inventors: Tatsuhiro SUWA, Yokohama-shi (JP); Takashige FUJIMORI, Yokohama-shi (JP); Atsuhito MURAI, Yokohama-shi (JP)

(21) Appl. No.: 19/648,651

(22) Filed: Apr. 15, 2026

Related U.S. Application Data
(63) Continuation of application No. PCT/KR2024/016221, filed on Oct. 23, 2024.

(30) Foreign Application Priority Data
Nov. 1, 2023 (JP) 2023-187558

(51) Int. Cl. H05K 5/30

(52) U.S. Cl. CPC H05K 5/30

(57) ABSTRACT

A tiling-type display device is provided. The tiling-type display device includes modules, each including at least a substrate, a light-emitting elements disposed on the substrate, and an electrode for applying voltage to the light-emitting element, wherein a seam between adjacent modules includes a resin, the difference ΔRI between a refractive index of the substrate and a refractive index of the resin in a visible light region is in a range of −0.01≤ΔRI≤0.01, and the bending elastic modulus of the seam is 35,500 MPa or less.

### CROSS-REFERENCE TO RELATED APPLICATION(S)

This application is a continuation application, claiming priority under 35 U.S.C. § 365(c), of an International application No. PCT/KR2024/016221, filed on Oct. 23, 2024, which is based on and claims the benefit of a Japanese patent application number 2023-187558, filed on Nov. 1, 2023, in the Japanese Intellectual Property Office, the disclosure of which is incorporated by reference herein in its entirety.

### BACKGROUND

### 1. Field

This disclosure relates to a tiling-type display device.

### 2. Description of Related Art

As a related art, widely known is a tiling-type display device in which a plurality of tiles shaped with regularity are arranged and connected as a unit module having a display unit on which a light-emitting element and the like is mounted. The tiling-type display device may provide a super-large screen based on the plurality of tiles being connected, and may be used in a scalable manner based on the number of tiles being adjusted. However, a seam between adjacent modules is discussed as a technical issue.

For example, in patent document 1, described is a transparent composite composition which is comprised of transparent resin (a) and a glassfiller (b), and of which the Abbe's number of the transparent resin (a) is greater than or equal to 45. Additionally, according to patent document 1, a difference in the refractive indices of the transparent resin (a) and the glassfiller (b) is preferably less than or equal to 0.01.
Patent Document 1: JP Laid-Open Patent Publication No. 2004-231934.

The above information is presented as background information only to assist with an understanding of the disclosure. No determination has been made, and no assertion is made, as to whether any of the above might be applicable as prior art with regard to the disclosure.

### SUMMARY

The transparent composite composition described in patent document 1 has a refractive index difference of less than or equal to 0.01 and the Abbe's number greater than or equal to 45, but there are cases where the refractive index difference is increased because of wavelengths, causing insufficient transparency of a display. Accordingly, when viewed in an oblique direction, the refraction of transparent light passing through a seam or the scattering of ambient light incident to the seam may be visible, thereby failing to secure sufficient seamlessness. Additionally, “seamlessness” means causing no scattering of ambient light resulting from scattering or reflection of transmitted light at the seam between modules, making it hard to see the seam.

Further, the transparent composite composition according to patent document 1 is appropriate for a rigid body such as a substrate or a lens and the like, when in use. Since a cured material is highly rigid and brittle, in the case where the transparent composite composition is used for a butt-welded portion (a seam) of a substrate included in a tiling-type display device, the transparent composite composition may be easily broken due to sagging or deformation at a time of handling.

Aspects of the disclosure are to address at least the above-mentioned problems and/or disadvantages and to provide at least the advantages described below. Accordingly, an aspect of the disclosure is to provide a means of securing improvement in the tenacity (toughness) of a seam as well as improvement in the seamlessness of the seam.

Additional aspects will be set forth in part in the description which follows and, in part, will be apparent from the description, or may be learned by practice of the presented embodiments.

In accordance with an aspect of the disclosure, a tiling-type display device is provided. The tiling-type display device includes modules each having at least a substrate, a light-emitting element mounted on the substrate, and an electrode that supplies a voltage to the light-emitting element are tiled, a seam between the modules adjacent to each other includes resin, a difference ΔRI between a refractive index of the substrate and a refractive index of the resin in a visible light region is in a range of −0.01≤ΔRI≤0.01, and a bending elastic modulus of the seam is less than or equal to 35,500 MPa.

According to various embodiments, a means of enhancing the tenacity (toughness) of a seam is provided, while the seamlessness of the seam is enhanced.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a view illustrating a tiling-type display device, and part (A) is a planar schematic view, part (B) is a cross-sectional schematic view cut along A-A, and part (C) is a cross-sectional schematic view cut along B-B according to an embodiment of the disclosure.

The same reference numerals are used to represent the same element throughout the drawing.

### DETAILED DESCRIPTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

In the disclosure, phrases such as “A or B,” “at least one of A and B,” “at least one of A or B,” “A, B or C,” “at least one of A, B and C,” and “at least one of A, B, or C” may include respectively any one possible combination or all possible combinations of the items listed together in the phrases. For example, “A or B,” “at least one of A and B,” or “at least one of A or B” may refer to all cases including (1) at least one A, (2) at least one B, or (3) both of at least one A and at least one B.

The terms such as “1^{st}”, “2^{nd},” or “first” or “second” may be used merely to differentiate one element from another, but not intended to limit elements in another aspect (e.g., their importance or order).

Based on one element (e.g., a first element) referred to as being “coupled with/to or connected with/to” another element (e.g., a second element) with or without the wording “operatively or communicatively”, it is to be understood that one element may be connected to another element directly (e.g., in a wired manner), in a wireless manner, or through yet another component (e.g., a third component).

The terms such as “include” or “have” and the like specify the presence of stated features, numbers, steps, operations, elements, parts or combinations thereof but do not imply the exclusion of the presence or addition of one or more other features, numbers, steps, operations, elements, parts or combinations thereof.

Based on one element referred to as being “connected with/to,” “coupled with/to,” “supporting,” or “contacting” another element, it is to be understood that one element is connected with/to another element, is coupled with/to another element, supports another element, or contacts another element directly or indirectly through a third element.

Based on one element referred to as being placed “on” another element, it is to be understood that one element contacts another element and that yet another element is present between the two elements.

The term “and/or” denotes including a combination or any of a plurality of relevant elements described.

In a certain situation, the expression “a device configured to . . . ” may denote “capable of being performed” by the device together with another device or other parts. For example, the phrase “a processor configured (or set) to perform A, B and C” may mean an exclusive processor (e.g., an embedded processor) for performing the functions, or a generic-purpose processor (e.g., a central processing unit (CPU) or an application processor) capable of performing the functions by executing one or more software programs stored in a memory device.

In the embodiments, the term “module” or “unit” may perform at least one function or operation, and be implemented by hardware or software or by a combination of hardware and software. Additionally, a plurality of “modules” or a plurality of “units” may be integrated into at least one module and implemented as at least one processor (not illustrated) excluding a “module” or a “unit” that needs to be implemented by specific hardware.

Further, unless described specifically, manipulation and measurement of a physical property and the like may be performed under the conditions of room temperature (greater than or equal to 20° C. and less than or equal to 25° C.)/relative humidity of greater than or equal to 40% RH and less than or equal to 50% RH.

According to at least one embodiment, in a tiling-type display device in which modules each having at least a substrate, a light-emitting element mounted on the substrate, and an electrode unit that supplies a voltage to the light-emitting element are tiled, a seam between the modules adjacent to each other includes resin, a difference ΔRI between a refractive index of the substrate and a refractive index of the resin in a visible light region is in a range of −0.01≤ΔRI≤0.01, and a bending elastic modulus of the seam is less than or equal to 35,500 MP. The tiling-type display device configured as described above secures improvement in the tenacity (toughness) of the seam, while securing improvement in the seamlessness of the seam.

Hereafter, the configuration of a light emitting diode (LED) display using an LED element as a light-emitting element 20 is described. However, a tiling-type display device 100 may be applied to another type of display such as an organic light-emitting diode (OLED) display, a liquid crystal display and the like as well as an LED display, in terms of display forms.

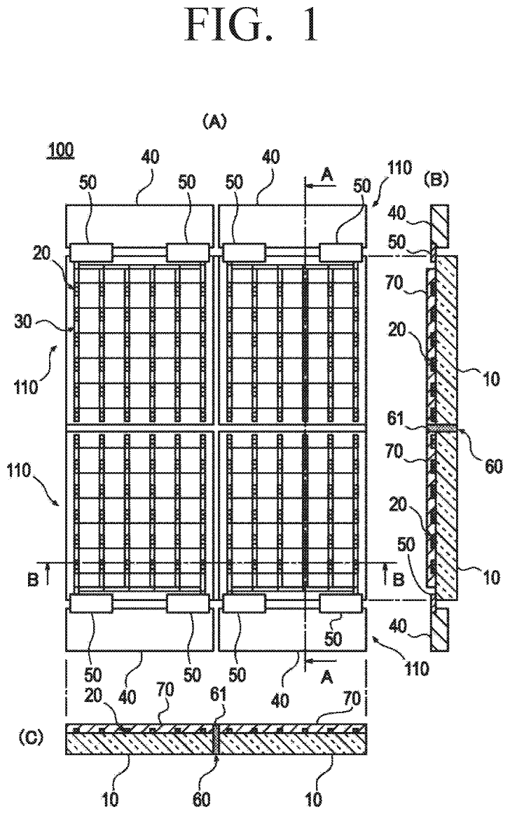

The configuration of the tiling-type display device 100 according to at least one embodiment is described properly with reference to FIG. 1. In the disclosure, a tile may be one independent display module, and a tiling-type display device may be a display device in which a plurality of display modules is connected to each other and used as one device. The tile may be referred to as various terms such as a module, a display, a display module, a display device and the like, and the tiling-type display device may be referred to as various terms such as a modular display device, an integrated display device and the like.

It should be appreciated that the blocks in each flowchart and combinations of the flowcharts may be performed by one or more computer programs which include instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g. a central processing unit (CPU)), a communication processor (CP, e.g., a modem), a graphics processing unit (GPU), a neural processing unit (NPU) (e.g., an artificial intelligence (AI) chip), a wireless fidelity (Wi-Fi) chip, a Bluetooth® chip, a global positioning system (GPS) chip, a near field communication (NFC) chip, connectivity chips, a sensor controller, a touch controller, a finger-print sensor controller, a display driver integrated circuit (IC), an audio CODEC chip, a universal serial bus (USB) controller, a camera controller, an image processing IC, a microprocessor unit (MPU), a system on chip (SoC), an IC, or the like.

However, FIG. 1 relates to a tiling-type display device 100, and the tiling-type display device 100 is not limited to a configuration described with reference to the drawings thereof.

FIG. 1 shows a planar schematic view and a cross-sectional schematic view of the tiling-type display device 100 according to an embodiment of the disclosure. In FIG. 1, part (A) shows a planar schematic view of the tiling-type display device 100, part (B) shows a cross-sectional schematic view cut along A-A of part (A) of FIG. 1, and part (C) shows a cross-sectional schematic view cut long B-B of FIG. 1.

Referring to FIG. 1, one tile, i.e., the module 110 includes a substrate 10, a light-emitting element 20, and an electrode unit 30.

As for the tiling-type display device 100, the module 110 at least having the substrate 10, the light-emitting element 20 mounted on a substrate surface (the surface) of the substrate 10, and the electrode unit 30 supplying a voltage required to drive the light-remitting element 20 is disposed with regularity in a matrix form, as illustrated in parts (A)-(C) of FIG. 1. A seam 60 that is a gap between the substrates 10 intervenes between the modules 110 adjacent to each other. The seam 60 may be described in various different terms such as a connection part, a bezel part, a gap region, a gap, a join part, a boundary part and the like.

In part (A) of FIG. 1, a total of four modules 110 disposed in a 2×2 form is illustrated. Additionally, the number of the modules 110 disposed in the tiling-type display device 100 may not be limited to that of part (A) of FIG. 1, and any numbers of modules 110 may be disposed. Further, the direction or shape of disposition of the module 110 may vary.

The tiling-type display device 100, as illustrated in part (A) of FIG. 1, has driving circuitry 40, and a flexible substrate 50 connecting the driving circuitry 40 and the electrode unit 30. The tiling-type display device 100 supplies a predetermined driving voltage to the electrode unit 30 through the flexible substrate 50 based on driving of the driving circuitry 40. As for the tiling-type display device 100, the light-emitting element 20 emits light to display predetermined display contents as a predetermined voltage is supplied to the light-emitting element 20 from the electrode unit 30.

The substrate 10 is comprised of a material such as alkali-free glass, polyimide, polyethylene terephthalate (PET), polyolefin, silicon and the like, enabling the light-emitting element 20 to be mounted. In the case of alkali-free glass, a glass substrate such as EAGLE XG™ and the like, may be properly used, for example. The material of the substrate 10 may not be limited to the above-described materials, and a proper material may be arbitrarily selected considering the flatness of a mounting surface of the light-emitting element 20 or heat-resistance and the like, at a time of mounting of the light-emitting element 20.

The light-emitting element 20 is comprised of a surface-mount device (SMD) LED element of each of the red green blue (RGB) colors and mounted on the substrate 10. The light-emitting element 20 constitutes three color elements in each pixel of the substrate 10, and emits light based on a voltage supplied from the electrode unit 30. As one example, the light-emitting element 20 may be implemented as an LED having the size of a micrometer unit.

The electrode unit 30 includes various types of cables connecting the light-emitting element 20 and the flexible substrate 50, or a thin film transistor (TFT). The electrode unit 30 may be connected with the driving circuitry 40 through the flexible substrate 50, and based on control of the driving circuitry 40, supplies a predetermined driving voltage to the light-emitting element 20.

### [Seam]

As for the tiling-type display device 100 of at least one embodiment, the seamlessness of reflected light and transmitted light at the seam 60 may improve, and the seamlessness of the seam 60 may be secured. Additionally, the tenacity (toughness) of the seam 60 may improve, and damage caused by sagging or deformation at a time of handling may be prevented.

The seam 60 between the modules 110 adjacent to each other is filled with resin 61. A refractive index difference ΔRI of the substrate 10 and the resin 61 in the visible light region is in a range of −0.01≤ΔRI≤0.01. In the case where the refractive index different ΔRI is outside the range, the seamlessness of the seam deteriorates. The refractive index difference ΔRI is more preferably in a range of −0.005≤ΔRI≤0.005, considering improvement in the seamlessness of the reflected light and the transmitted light at the seam 60 and ease of a guarantee of the seamlessness of the seam 60. The refractive index difference ΔRI may be controlled by properly selecting the sort of resin (e.g., the sort or quantity ratio and the like of an epoxy compound included in an adhesive composition).

The refractive index difference ΔRI may be obtained by measuring refractive indices nd, nf and nc with respect to wavelengths of sodium D-line (589 nm), hydrogen F-line (486.13 nm) and hydrogen C-line (656.27 nm) of the substrate and the resin by using Abbe's refractomer, based on a test method conforming to the JIS K7142:2014 standard. In greater detail, the refractive index difference may be obtained based on a method described with reference to the embodiments.

As for the tiling-type display device 100 of one embodiment, a bending elastic modulus of the seam is less than or equal to 35,500 MPa. In the case where the bending elastic modulus exceeds 35,500 MPa, even a slight deformation may cause damage to the seam (peeling (coming off) at the interface between the substrate and the resin or, breakage of the resin, the substrate and the like).

The bending elastic modulus of the seam is preferably less than or equal to 32,000 MPa, more preferably less than or equal to 22,000 MPa, and most preferably less than or equal to 17,000 MPa. Additionally, a minimum value of the bending elastic modulus of the seam is not specifically limited, but is preferably greater than or equal to 500 MPa, more preferably greater than or equal to 1,000 MPa, and most preferably greater than or equal to 4,000 MPa. Accordingly, the bending elastic modulus of the seam may be preferably greater than or equal to 500 MPa and less than or equal to 32,000 MPa, more preferably greater than or equal to 1,000 MPa and less than or equal to 22,000 MPa, and most preferably greater than or equal to 4,000 MPa and less than or equal to 17,000 MPa.

The bending elastic modulus of the seam, in greater detail, employs a value measured based on the method described with reference to the embodiment. Additionally, the bending elastic modulus, like the refractive index difference ΔRI described above, may be controlled by properly selecting the sort of resin (e.g., the sort or quantity ratio and the like of an epoxy compound included in an adhesive composition).

### <Resin>

As for the tiling-type display device of one embodiment, the seam include resin. Regarding an optical feature of the resin, haze in light source D65 is preferably less than or equal to 10%, and more preferably less than or equal to 5%. Additionally, the haze may be measured based on a method described with reference to JIS K7136 (2000).

Examples of the resin may include acrylic resin, silicone resin, urethane resin, polyester resin and a combination thereof. Additionally, examples of the resin may include a cured material of an adhesive composition including an epoxy compound. Among the examples, the resin may include a cured material of an adhesive composition including an epoxy compound, for the embodiments of the disclosure to produce more significant effects. Hereafter, the adhesive composition including the epoxy compound is described.

[symbol]

Adhesive Composition

[symbol]

The adhesive composition according to the embodiments includes an epoxy compound. The epoxy compound means a compound containing an epoxy group. Specific examples of the epoxy compound may include an aliphatic epoxy compound, a cycloaliphatic epoxy compound, an aromatic epoxy compound and the like. One sort of epoxy compound may be used solely or two or more sorts of epoxy compounds may be used in combination as the epoxy compound. Additionally, a synthetic product or a commercial product may be used as the epoxy compound. Further, a compound having a functional group reacting with an epoxy group may also be used. The function group may include an oxetane group, an episulfide group, an alcoholic hydroxyl group, a phenolic hydroxyl group, a carboxyl group, an acid anhydride group, an amino group and the like.

The aliphatic epoxy compound is an acyclic epoxy compound containing no aromatic group and no cycloaliphatic group. Specific examples of the aliphatic epoxy compound may include aliphatic polyhydric alcohol or polyglycidyl ether of an alkylene oxide adduct thereof, polyglycidyl ester of aliphatic long acyclic polybasic acid, homopolymer synthetized based on vinyl polymerization of glycidyl acrylate or glycidyl methacrylate, copolymer synthetized based on vinyl polymerization between glycidyl acrylate or glycidyl methacrylate and another vinyl monomer, and the like. For example, representative compounds may include glycidyl ether of polyhydric alcohol such as 1,4-butanediol diglycidyl ether, 1, 6-hexanediol diglycidyl ether, triglycidyl ether of glycerin, diglycidyl ether of trimethylolpropane, triglycidyl ether of trimethylolpropane, tetraglycidyl ether of sorbitol, hexaglycidyl ether of dipentaerythritol, diglycidyl ether of polyethylene glycol, diglycidyl ether of polypropylene glycol and the like, and may include polyglycidyl ether of polyether polyol obtained by adding one or more sorts of alkylene oxide to aliphatic polyhydric alcohol such as propyleneglycol, trimethylolpropane, glycerin and the like, diglycidyl ester of aliphatic long acyclic polybasic acid. Additionally, the compounds may include monoglycidyl ether of aliphatic higher alcohol, or phenol, cresol, butylphenol, or monoglycidyl ether of polyether alcohol obtained by adding alkylene oxide to phenol, cresol, butylphenol, glycidyl ester of higher fatty acid, epoxidized soybean oil, epoxystearic acid octyl, epoxystearic acid butyl, epoxide polybutadiene, and the like.

A commercial product may be used as the aliphatic epoxy compound. The commercial product, for example, may include DENACOL™ EX-121, DENACOL EX-171, DENACOL EX-192, DENACOL EX-211, DENACOL EX-212, DENACOL EX-214L, DENACOL EX-313, DENACOL EX-314, DENACOL EX-321, DENACOL EX-411, DENACOL EX-421, DENACOL EX-512, DENACOL EX-521, DENACOL EX-611, DENACOL EX-612, DENACOL EX-614, DENACOL EX-622, DENACOL EX-810, DENACOL EX-811, DENACOL EX-850, DENACOL EX-851, DENACOL EX-821, DENACOL EX-830, DENACOL EX-832, DENACOL EX-841, DENACOL EX-861, DENACOL EX-911, DENACOL EX-941, DENACOL EX-920, DENACOL EX-931, DENACOL EX-931L (above, products of Nagase ChemteX Corp.), EPOLYTE M-1230, EPOLYTE 40E, EPOLYTE 100E, EPOLYTE 200E, EPOLYTE 400E, EPOLYTE 70P, EPOLYTE 200P, EPOLYTE 400P, EPOLYTE 1500NP, EPOLYTE 1600, EPOLYTE 80MF, EPOLYTE 100MP, ADEKA GLYCIROL ED-503, ADEKA GLYCIROL ED-503G, ADEKA GLYCIROL ED-506, ADEKA GLYCIROL ED-523T, ADEKA RESINE EP-4088S, ADEKA RESINE EP-4080E (above, products of ADEKA Corp.) and the like.

The cycloaliphatic epoxy compound is an epoxy compound having a cycloaliphatic group. In detail, polyglycidyl ether of polyhydric alcohol having at least one cycloaliphatic group, cyclohexene oxide obtained by epoxidizing a compound containing a cyclohexene or cyclopentene ring with an oxidizer or a compound containing cyclopentene oxide, a compound where an epoxy group is bonded to a cycloaliphatic group directly in a single bond and the like. In greater detail, the cycloaliphatic epoxy compound, for example, may include hydrogenated bisphenol A diglycidyl ether, 3, 4-epoxycyclohexyl methyl-3, 4-epoxycyclohexanecarboxylate, 3-4-epoxy-1-methylcyclohexane-3, 4-epoxy-1-methyl hexanecarboxylate, 6-methyl-3, 4-epoxycyclohexylmethyl-6-methyl-3, 4-epoxycyclohexanecarboxylate, 3, 4-epoxy-3-methyl cyclohexyl methyl-3, 4-epoxy-3-methyl cyclohexanecarboxylate, 3, 4-epoxy-5-methyl cyclohexyl methyl-3, 4-epoxy-5-methyl cyclohexanecarboxylate, 2-(3, 4-epoxycyclohexyl-5, 5-spiro-3, 4-epoxy) cyclohexane-metadioxane, bis(3, 4-epoxycyclohexyl methyl) adipate, 3, 4-epoxy-6-methyl cyclohexylcarboxylate, methylenebis(3, 4-epoxycyclohexane), dicyclopentadiene diepoxide, ethylenebis(3, 4-epoxycyclohexanecarboxylate), epoxyhexahydrophthalic acid dioctyl, epoxyhexahydrophthalic acid di-2-ethylhexyl, 1-epoxyethyl-3, 4-epoxycyclohexane, 1-2-epoxy-2-epoxy ethylcyclohexane, 3, 4-epoxycyclohexyl methyl acrylate, 3, 4-epoxycyclohexyl methyl methacrylate, 2, 2-bis(hydroxymethyl)-1-butanol-1, 2-epoxy-4-(2-oxiranyl) cyclohexane adducts and the like.

A commercial product may be used as the cycloaliphatic epoxy compound. The commercial product, for example, may include UVR-6100, UVR-6105, UVR-6110, UVR-6128, UVR-6200 (above, products of Union Carbide Corp.), CELLOXIDE™ 2021, CELLOXIDE 2021P, CELLOXIDE 2081, CELLOXIDE 2083, CELLOXIDE 2085, CELLOXIDE 2000, CELLOXIDE 3000, CYCLOMER™ A200, CYCLOMER M100, CYCLOMER M101, EPOLEAD™ GT-301, EPOLEAD GT-302, EPOLEAD 401, EPOLEAD 403, ETHB, EPOLEAD HD300, EHPE 3150, EHPE 3150CE (above, products of DAICEL Corp.), ADEKA ARKLS KRM-2110, ADEKA ARKLS KRM-2199 (above, products of ADEKA Corp.) and the like.

The aromatic epoxy compound is an epoxy compound including an aromatic group. The aromatic epoxy compound may include phenols having at least one aromatic ring such as phenol, cresol, butylphenol and the like, or a mono/polyglycidyl ether compound of an alkylene oxide adduct of phenols, e.g., bisphenol A, bisphenol F, or a glycidyl ether compound of a compound where alkylene oxide is further added to bisphenol A, bisphenol F or novolac epoxy resin; a mono/polyglycidyl ether compound of an aromatic compound having two or more phenolic hydroxyl groups such as resorcinol or hydroquinone, catechol and the like; a glycidyl ether compound of an aromatic compound having two or more alcoholic hydroxyl groups such as phenyl dimethanol or phenyl diethanol, phenyl dibutanol and the like; glycidyl ester of a polybasic acid aromatic compound having two or more carboxylic acids such as phthalic acid, terephthalic acid, trimellitic acid and the like, glycidyl ester of benzoic acid, styrene oxide or epoxide of divinylbenzene and the like.

A commercial product may be used as the aromatic epoxy compound. The commercial product, for example, may include DENACOL EX-141, DENACOL EX-146, DENACOL EX-147, DENACOL EX-201, DENACOL EX-203, DENACOL EX-711, DENACOL EX-721, On-Coat™ EX-1020, On-Coat EX-1030, On-Coat EX-1040, On-Coat EX-1050, On-Coat EX-1051, On-Coat EX-1010, On-Coat EX-1011, On-Coat 1012 (above, products of Nagase ChemteX Corp.); OGSOL™ PG-100, OGSOL EG-200, OGSOL EG-210, OGSOL EG-250 (Above, products of OSAKA GAS CHEMICALS Corp.); HP4032, HP4032D, HP4700 (above, products of DIC Corp.); ESN-475V; jER™ YX8800; MARPROOF™ G-0105SA, MARPROOF G-0130SP; EPICLON™ N-665, EPICLON HP-7200 (above, products of DIC Corp.); EOCN-1020, EOCN-102S, EOCN-103S, EOCN-104S, XD-1000, NC-3000, EPPN-501H, EPPN-501HY, EPPN-502H, NC-7000L (above, products of NIPPON KAYAKU Corp.); ADEKA RESINE™ EP-4000, ADEKA RESINE EP-4005, ADEKA RESINE EP-4100, ADEKA RESINE EP-4901 (above, products of ADEKA Corp.); and the like.

Epoxy equivalent weight of the epoxy compound is preferably greater than or equal to 80 g/eq., more preferably greater than or equal to 95 g/eq., and most preferably greater than or equal to 110 g/eq. In the case where the epoxy equivalent weight of the epoxy compound is greater than or equal to 80 g/eq., the reactivity of a cured material, and the strength of a cured material obtained by curing an adhesive composition are excellent. Additionally, the epoxy equivalent weight of the epoxy compound is preferably less than or equal to 5,000 g/eq., more preferably less than or equal to 3,000 g/eq., and most preferably less than or equal to 2,000 g/eq. In the case where the epoxy equivalent weight of the epoxy compound is less than or equal to 5,000 g/eq., molecular weight between cross-linking points is high, and accordingly, the flexibility of a cured material obtained by curing an adhesive composition is excellent. In this context, the epoxy equivalent weight of the epoxy compound is preferably greater than or equal to 80 g/eq. and less than or equal to 5,000 g/eq., more preferably greater than or equal to 95 g/eq. and less than or equal to 3,000 g/eq., and most preferably greater than or equal to 110 g/eq. and less than or equal to 2,000 g/eq., for example. Additionally, the epoxy equivalent weight may be measured based on JIS K7236:2001.

For the embodiments of the disclosure to produce more significant effects, the epoxy compound preferably includes an epoxy compound of which epoxy equivalent weight is greater than or equal to 250 g/eq. Since such an epoxy compound is used, a highly flexible structure may be secured, and as molecular weight between cross-linking points is high after curing, toughness of resin may be enhanced. In the case of an epoxy compound of epoxy equivalent weight greater than or equal to 250 g/eq., a maximum value of the epoxy equivalent weight is not limited, but preferably less than or equal to 5,000 g/eq., more preferably less than or equal to 3,000 g/eq., and most preferably less than or equal to 2,000 g/eq.

Additionally, the content of the epoxy compound of epoxy equivalent weight greater than or equal to 250 g/eq. in an adhesive composition is preferably greater than or equal to 10 mass %, more preferably greater than or equal to 15 mass %, and most preferably greater than or equal to 20 mass % with respect to total mass of the adhesive composition. Further, the content of the epoxy compound of epoxy equivalent weight greater than or equal to 250 g/eq. in an adhesive composition is preferably less than or equal to 70 mass %, more preferably less than or equal to 65 mass %, and most preferably less than or equal to 60 mass % with respect to total mass of the adhesive composition. In this context, the content of the epoxy compound of epoxy equivalent weight greater than or equal to 250 g/eq. in an adhesive composition is preferably greater than or equal to 10 mass % and less than or equal to 70 mass %, more preferably greater than or equal to 15 mass % and less than or equal to 65 mass %, and most preferably greater than or equal to 20 mass % and less than or equal to 60 mass %, for example.

Furthermore, one sort of epoxy compound of epoxy equivalent weight greater than or equal to 250 g/eq. may be used solely or two or more sorts of epoxy compounds may be used in combination. In the case where two or more sorts of epoxy compounds of epoxy equivalent weight greater than or equal to 250 g/eq. are used, the content of the epoxy compounds means an added amount thereof.

For the embodiments of the disclosure to produce more significant effects, the epoxy compound of epoxy equivalent weight greater than or equal to 250 g/eq. is preferably an aliphatic acyclic epoxy compound containing no aromatic group or no cycloaliphatic group. In the same context, the epoxy compound of epoxy equivalent weight greater than or equal to 250 g/eq. more preferably has an aliphatic acyclic ether structure. The epoxy compound of epoxy equivalent weight greater than or equal to 250 g/eq. is most preferably polypropylene glycol diglycidyl ether.

An adhesive composition may ring-opening polymerize and cure an epoxy group. Energy for polymerization is not limited, but heat and active energy rays may be used for polymerization. In other words, the adhesive composition may be thermally curable, or active energy ray curable. In the case where the adhesive composition is cured by heat, the adhesive composition may contain a curing agent or a thermal acid generator, a thermal base generator. In the case where the adhesive composition is cured by active energy rays, the adhesive composition may contain a photoinitiator, a photoacid generator, a photobase generator.

The adhesive composition may be an active energy ray cure-type adhesive composition in which an epoxy compound is polymerized and cured based on irradiation of active energy rays such as ultraviolet rays, visible light, X-rays or electron beams and the like. The adhesive composition may also be an ultraviolet cure-type adhesive composition that is cured based on irradiation of ultraviolet rays. In the case where the adhesive composition is an ultraviolet cure-type adhesive composition, a cumulative amount of ultraviolet light at a time of curing may be greater than or equal to 100 mJ/cm² or greater than or equal to 1000 mJ/cm², and less than or equal to 10000 mJ/cm² or less than or equal to 8000 mJ/cm², for example. Ultraviolet rays irradiated to the adhesive composition may be Ultraviolet A (UVA) (wavelengths greater than or equal to 320 nm and less than or equal to 400 nm), Ultraviolet B (UVB) (wavelengths greater than or equal to 280 nm and less than or equal to 320 nm), or Ultraviolet C (UVC) (wavelengths greater than or equal to 200 nm and less than or equal to 280 nm).

The adhesive composition preferably includes a photoacid generator. Accordingly, the epoxy compound included in the adhesive composition is cured based on cation-polymerization, and a proper cured material of the adhesive composition may be formed as resin. The photoacid generator is to generate cationic species or Lewis acid and initiate a polymerization reaction of an epoxy compound, based on irradiation of active energy rays. The photoacid generator acts catalytically by light, and accordingly, even in the case where the photoacid generator is mixed to the epoxy compound, reliable preservation and work efficiency are secured. The photoacid generator, for example, may include aromatic diazonium salt; onium salt of aromatic iodonium salt and aromatic sulfonium salt and the like; an iron-arene coordination compound and the like.

The aromatic diazonium salt, for example, may include the following:
benzenediazonium hexafluoroantimonate;
benzenediazonium hexafluorophosphate;
benzenediazonium hexafluoroborate; and

the like.

The aromatic iodonium salt, for example, may include the following:
diphenyliodonium tetrakis(pentafluorophenyl)borate;
diphenyliodonium hexafluorophosphate;
diphenyliodonium hexafluoroantimonate;
di(4-nonylphenyl) iodonium hexafluorophosphate; and

the like.

The aromatic sulfonium salt, for example, may include the following:
triphenylsulfonium hexafluorophosphate;
triphenylsulfonium hexafluoroantimonate;
triphenylsulfonium tetrakis(pentafluorophenyl)borate;
diphenyl(4-(phenylthio)-phenyl) sulfonium hexafluorophosphate;
4, 4′-bis(diphenylsulfonio) diphenyl sulfide bis hexafluorophosphate;
4, 4′-bis [di(β-hydroxyethoxy) phenylsulfonio] diphenyl sulfide bishexafluoroantimonate;
4, 4′-bis [di(β-hydroxyethoxy) phenylsulfonio] diphenyl sulfide bis hexafluorophosphate;
7-[di(p-toluic) sulfonio]-2-isopropylthioxanthone hexafluoroantimonate;
7-[di(p-toluic) sulfonio]-2-isopropylthioxanthone tetrakis(pentafluorophenyl)borate;
4-phenylcarbonyl-4′-diphenylsulfonio-diphenyl sulfide hexafluorophosphate;
4-(p-tert-butylphenylcarbonyl)-4′-diphenylsulfonio-diphenyl sulfide hexafluoroantimonate;
4-(p-tert-butylphenylcarbonyl)-4′-di(p-toluic) sulfonio-diphenyl sulfide tetrakis(pentafluorophenyl)borate; and

the like.

The iron-arene coordination compound, for example, may include the following:
xylene-cyclopentadienyliron(II) hexafluoroantimonate;
cumene-cyclopentadienyliron(II) hexafluorophosphate;
xylene-cyclopentadienyliron(II) tris(trifluoromethanesulfonyl) methanide; and

the like.

One sort of photoacid generator may be used solely or two or more sorts of photoacid generators may be used in combination. Among the above salts, since the aromatic sulfonium salt has a property of absorbing ultraviolet rays even in a wavelength region around 300 nm, the aromatic sulfonium salt secures excellent curability and is used preferably.

A synthetic product or a commercial product may be used as the aromatic sulfonium salt. The commercial product of the aromatic sulfonium salt, for example, may include WPAG-336, WPAG-367, WPAG-370, WPAG-469, WPAG-638, CPI™-100P, CPI-101A, CPI-200K, CPI-201S (above, products of San-Apro Ltd.), ADEKA ARKLS™ SP-056, ADEKA ARKLS SP-066, ADEKA ARKLS SP-130, ADEKA ARKLS SP-140, ADEKA ARKLS SP-082, ADEKA ARKLS SP-103, ADEKA ARKLS SP-601, ADEKA ARKLS SP-606, ADEKA ARKLS SP-701, ADEKA ARKLS SP-150, ADEKA ARKLS SP-170 (above, products of ADEKA Corp.) and the like.

The content of (solid content) of the photoacid generator in the adhesive composition is preferably greater than or equal to 0.25 parts by mass, more preferably greater than or equal to 0.5 parts by mass, and most preferably greater than or equal to 0.75 parts by mass, with respect to 100 parts by mass of the epoxy compound. The content of (solid content) of the photoacid generator in the adhesive composition is preferably less than or equal to 5.0 parts by mass, more preferably less than or equal to 4.0 parts by mass, and most preferably less than or equal to 3.0 parts by mass, with respect to 100 parts by mass of the epoxy compound. In other words, the content of (solid content) of the photoacid generator in the adhesive composition is preferably greater than or equal to 0.25 parts by mass and less than or equal to 5.0 parts by mass, more preferably greater than or equal to 0.5 parts by mass and less than or equal to 4.0 parts by mass, and most preferably greater than or equal to 0.75 parts by mass and less than or equal to 3.0 parts by mass, with respect to 100 parts by mass of the epoxy compound. In the case where two or more sorts of photoacid generators are included in the adhesive composition, the content of the photoacid generators means an added amount thereof.

The adhesive composition may include other ingredients in addition to the epoxy compound and the photoacid generator. The other ingredients may include a photosensitizer, a photosensitizing agent, a polymerization accelerator, an ion trapping agent, an antioxidant, a light stabilizer, a chain transfer agent, a tackifier, thermoplastic resin, a filler, a flow control agent, a plasticizer, a defoamer, an antistatic agent, a leveling agent, pigment, an organic solvent and the like.

A method of preparing an adhesive composition is not limited, and each of the ingredients included in an adhesive composition may be stirred and mixed to obtain the adhesive composition. Temperature or time at a time of mixture is not limited. The order of the mixture is not limited, and a method of mixing each of the ingredients in a batch, a method of mixing each of the ingredients sequentially and the like may be employed.

Resin is used to secure the seamlessness of the seam 60 while enhancing the seamlessness of reflected light and transmitted light at the seam 60, and in the case where a substrate of which cables and the like are not processed is tiled, an optical property is preferably set to be in a range of [(a haze of a seam)−(a haze of a non-seam)]≤1.0. Herein, [(a haze of a seam)−(a haze of a non-seam)] ΔH may be measured based on the method described with reference to the embodiment.

According to one embodiment, a pigmentable transparent resin pigmented with a predetermined color may be used as the resin 61 filling the seam 60. A color close to the color of the electrode unit 30 may be used for the pigmentable transparent resin in terms of visibility. As one example, pigment or dye may be mixed such that the pigmentable transparent resin has shades of a color such as shades of black, shades of brown, shades of yellow in accordance with the color of the electrode unit 30.

In the case where the cured material of the adhesive composition is used as resin, a connection method of the seam is not limited, but for example, may involve touching cut portions of cut glass substrates each other, dropping the adhesive composition on the cut portions (connected portions) touched each other, and then curing the adhesive composition, to obtain the seam.

In the case of a tiling-type display device 100, a molding layer 70 with a thickness less than or equal to half the thickness of the substrate 10 may be formed to cover the light-emit element 20. The molding layer 70 may be comprised of silicone resin or epoxy resin and the like, and silicone resin may be used for the molding layer from a heat-resistance perspective.

A method of forming a layer-shaped member for constituting at least part of the molding layer 70 is not limited, and for example, the layer-shaped member may be formed based on a known method including a solution casting method, a melting point method, an application method, a sputtering method, a deposition method, an ion plating method, a chemical vapor deposition (CVD) method and the like.

Though not illustrated in FIG. 1, the tiling-type display device may have a protective layer on one surface or both surfaces of the substrate to enhance strength such as impact resistance and the like. The protective layer may be formed with glass or an organic resin film. In the case of an organic resin film, a resin film usable as an optical film may be applied, for example, and the material for the organic resin film may include polyester (PET) such as polyethylene terephthalate (PET) and the like, triacetyl cellulose (TAC), poly (methyl methacrylate) (PMMA), polycarbonate (PC) and the like, for example. The tiling-type display device may have an adhesive layer to stick the protective layer to the substrate 10, and the adhesive layer may include resin selected from a group consisting of acrylic resin, urethane resin, epoxy resin, silicone resin and a combination thereof.

Though not illustrated in FIG. 1, as for the tiling-type display device, a low reflection part may be formed in at least one direction of the surface of the protective layer and the surface of the seam. The low reflection part may have at least one of an element comprised of a film formed with a low reflection material (e.g., black matrix resin containing a black material), and an element on which predetermined surface processing is performed to ensure low reflection (e.g., anti-reflection (AR) processing, low reflection (LR) processing, anti-glare (AG) processing or a combination thereof).

According to the disclosure, the tiling-type display device having the above-described element may suppress deterioration of seamlessness, caused by reflection of ambient light and refraction/scattering of transmitted light, at the seam. Additionally, since the seam 60 may become seamless, seamlessness in an oblique direction as well as seamlessness from the front may be expected to improve. Accordingly, the tiling-type display device of the disclosure may have an exterior such as an exterior of a glass module of one sheet, and from a small-sized display to a large-sized display, may be properly used for a transmissive device widely. Further, the tiling-type display device according to the disclosure secures improvement in tenacity of the seam, and is hardly broken despite sagging or deformation at a time of handling.

The embodiments of the disclosure are described in detail, but are provided merely as illustrative and descriptive examples and not limited. Obviously, the scope of the matter of the disclosure is to be interpreted according to the attached claims.

A tiling-type display device according to at least one embodiment may employ the following form and shape.
1. A tiling-type display device in which modules each having at least a substrate, a light-emitting element mounted on the substrate, and an electrode unit supplying a voltage to the light-emitting element are tiled, wherein a seam between the modules adjacent to each other includes resin, a difference ΔRI between a refractive index of the substrate and a refractive index of the resin in a visible light region is in a range of −0.01≤ΔRI≤0.01, and a bending elastic modulus of the seam is less than or equal to 35,500 MPa:
2. The tiling-type display device described above in 1, wherein the resin includes a cured material of an adhesive composition including an epoxy compound:
3. The tiling-type display device described above in 2, wherein the epoxy compound includes an epoxy compound of epoxy equivalent weight greater than or equal to 250 g/eq:
4. The tiling-type display device described above in 3, wherein content of the epoxy compound of epoxy equivalent weight greater than or equal to 250 g/eq. is greater than or equal to 10 mass %, with respect to total mass of the adhesive composition:
5. The tiling-type display device described above in 3 or 4, wherein the epoxy compound of epoxy equivalent weight greater than or equal to 250 g/eq. is an aliphatic acyclic epoxy compound containing no aromatic group and no cycloaliphatic group:
6. The tiling-type display device described above in any of 3-5, wherein the epoxy compound of epoxy equivalent weight greater than or equal to 250 g/eq. has an aliphatic acyclic ether structure:
7. The tiling-type display device described above in any of 3-6, the epoxy compound of epoxy equivalent weight greater than or equal to 250 g/eq. is poly propylene glycol diglycidyl ether:
8. The tiling-type display device described above in any of 1-7, wherein a difference ΔRI between a refractive index of the substrate and a refractive index of the resin in a visible light region is −0.005≤ΔRI≤0.005; and
9. The tiling-type display device described above in any of 1-8, wherein, wherein the tiling-type display device is a transmissive device.

### Embodiments

The effects of the embodiments of the disclosure are described in greater detail. However, the technical scope of the matter of the disclosure is not limited only to the embodiments described hereafter.

### (Preparation of Adhesive Composition 1)

To prepare adhesive agent 1 of a liquid phase, 20 g of DENACOL™ EX-141(phenyl glycidyl ether, epoxy equivalent weight: 151 g/eq.), 42 g of DENACOL™ EX-931 (epoxy equivalent weight: 471 g/eq.), and 38 g of EHPE3150CE (epoxy equivalent weight: 177 g/eq.) were mixed and prepared in a uniform solution, and then mixed with 2.5 g of CPI-100P as a photoacid generator.

### (Preparation of Adhesive Compositions 2-8)

Adhesive compositions 2-8 were prepared based on the same method as that of the above (preparation of adhesive agent 1), excluding changes in the composition in table 1 shown hereafter. Additionally, each of the ingredients in table 1 shown hereafter are described as follows, and “-” in table 1 shown hereafter indicates containing none of a corresponding ingredient.
EX-141: DENACOL EX-141 (phenyl glycidyl ether, epoxy equivalent weight: 151 g/eq.)
EX-214L: DENACOL EX-214L (1, 4-butanediol diglycidyl ether, epoxy equivalent weight: 115 g/eq.)
EX-321: DENACOL EX-321 (trimethylolpropane polyglycidyl ether, epoxy equivalent weight: 140 g/eq.)
EX-931: DENACOL EX-931 (poly propylene glycol diglycidyl ether, epoxy equivalent weight: 471 g/eq.)
EHPE3150CE: EHPE3150CE (a 1, 2-epoxy-4-(2-oxiranyl) cyclohexane adduct of 2, 2-bis(hydroxymethyl)-1-butanol, epoxy equivalent weight: 177 g/eq.)
CE2021P: CELLOXIDE 2021P (3, 4-epoxycyclohexyl methyl-3′, 4′-epoxycyclohexanecarboxylate, DAICEL: 133 g/eq.)
CPI-100P: a 50% solution of propylene carbonate of diphenyl 1-4-(phenylthio)-phenyl sulfonium hexafluorophosphate.

TABLE 1

| Adhesive | | | | | | | |
|---|---|---|---|---|---|---|---|
| composition | Composition (g) | | | | | | |
| No. | EX-141 | EX-214L | EX-321 | EX-931 | EHPE3150OCG | CE2021P | CPI-100P |
| 1 | 20 | — | — | 42 | — | 38 | 2.5 |
| 2 | 20 | — | — | 50 | 30 | — | 2.5 |
| 3 | 10 | — | — | 40 | 22 | 28 | 2.5 |
| 4 | 10 | 8 | — | 30 | 22 | 30 | 2.5 |
| 5 | 10 | 20 | — | 30 | 40 | — | 2.5 |
| 6 | — | 58 | — | — | 22 | 20 | 2.5 |
| 7 | — | — | 80 | — | — | 20 | 2.5 |
| 8 | — | — | 40 | — | 60 | — | 2.5 |

### [Preparation of Sample for Evaluation]

Adhesive compositions 1-8 obtained in the above were used to prepare two sorts of samples (evaluation element A, evaluation element 2) used for each evaluation through processes 1-7 or processes 1-8 described hereafter.

Process 1: EAGLE XG™ of 150 mm×70 mm×05 mm cut in a central portion was prepared as a glass substrate.

Process 2: The glass prepared in process 1 adhered onto a silicone non-adhesive sheet in the way that cut portions were touched each other with a gap of 100 μm therebetween.

Process 3: The adhesive compositions obtained in the embodiments and comparative examples were dropped onto the connected portions (hereafter, referred to as a seam) touched each other, and infiltrated into the seam.

Process 4: After the infiltration of the adhesive compositions into the seam was checked, the adhesive compositions were allowed to flow to a short edge of the glass in a line shape, and a handroller was used to stick a silicone non-adhesive sheet in the way that the adhesive compositions were fitted, and then a uniform adhesive layer was coated on the glass plate.

Process 5: The adhesive compositions irradiated with ultraviolet rays by using black light (a blacklight blue fluorescent lamp, was cured, from the coated surface of the adhesive compositions. At that time, a cumulative amount was 6000 mJ/cm 2 (a light meter (main body UVPF-A1, light-receiving part PD-365 (both of which are products of IWASAKI ELECTRIC CO. LTD.)).

Process 6: The adhesive composition-coated samples were turned over to peel a silicone non-adhesive sheet, and an adhesive agent solution was allowed to flow to a short edge of the glass in a line shape, and a handroller was used to stick a silicone non-adhesive sheet in the way that the adhesive agent was fitted, and then a uniform adhesive layer was coated on the glass plate.

Process 7: Under the conditions the same as those of process 5, the adhesive agent was cured by irradiating ultraviolet rays with black light, from the coated surface of the adhesive agent, and after the curing, a portion sticking out from the glass was removed with a knife. The obtained cured material (resin) of the adhesive agent was stored at room temperature of 25° C. for one or more days, and then provided for an evaluation. Additionally, this element is referred to as evaluation element A.

Process 8: A 100 μm-thickness polyethylene terephthalate (PET) film to which a 100 μm-thickness adhesive layer was preliminarily laminated, bonded to the coated surface of the adhesive agent from which the silicone non-adhesive sheet on the coated surface side of the adhesive agent in process 7 was peeled off. Additionally, this element is referred to as evaluation element B.

### [Evaluation: Measurement of Bending Elastic Modulus]

A three-point bending test jig was set on Texture Analyzer. A distance between points was 40 mm. The thickness of a sample of evaluation element A of which the silicone non-adhesive sheet was peeled from both surfaces was measured with a film thickness gauge, and then the seam was installed on a point to make the seam a center. A load was given at an insertion speed of 5 mm/min, a position at which the load started to be generated was determined as 0, a position at which the sample was broken was determined as an amount of change Δs in sagging, a load at the time of breakage was determined as an amount of change ΔF in bending load, and a bending elastic modulus E (unit: MPa) of the seam was calculated with the following equation.

$$Bending elastic modulus E = \frac{{L}^{3}}{4 {bh}^{3}} \times \frac{Δ F}{Δ s} \qquad Equation 1$$

ΔF: amount of change in bending load Δs: amount of change in sagging
L: distance between points b: width of sample piece H: thickness of sample piece

### [Evaluation: Breakage Resistance Test]

A short edge on one side of the sample of evaluation element B from which the silicone non-adhesive sheet was peeled was placed on a test table with the adhesive surface of PET as an upper surface, and a short edge on the other side was placed on an end portion of 0.5 mm-thickness glass placed on the test table, to form a 0.5 mm-step on a long edge of the sample of evaluation element B. The sample of evaluation element B was pressed with a handroller from the end portion placed on the test table side, and a breakage state of the seam was observed after the press. In the case where no breakage occurred, the step was increased by 0.5 mm until the seam was broken or the glass part was broken. A maximum height at which no breakage occurred was determined as a characteristic value of the breakage resistance test.

### [Evaluation: Measurement of Optical Property]

Haze meter NDH5000W was used to measure hazes of the seam and non-seam of the sample of evaluation element A of which the silicone non-adhesive sheet was peeled from both surfaces, and a difference (the haze of the seam and the haze of the non-seam, ΔH) was obtained.

### [Evaluation: Sensory Test of Visibility]

The sample of evaluation element A of which the silicone non-adhesive sheet was peeled from both surfaces was fixed to a window, and the seam was observed at different angles in a place that was one meter far away from the seam to perform a sensory test. Based on a result of the sensory test, as long as the seam is almost not seen, or the seam is seen in a blurred manner, the sample can be used.

### [Evaluation: Measurement of Refractive Index]

Two fluoro resin plates of 20 mm×30 mmx 1 mm were prepared, one of them had a hole of 5 mm×20 mm in a central portion thereof, and the two plates were overlapped and fixed by clipping the end portions thereof. Then the hole was filled with the adhesive compositions obtained in the above-described embodiments and comparative examples, and under the conditions the same as those of process 5, ultraviolet rays were irradiated with black light, to prepare a cured material (resin) of the adhesive compositions. The cured material (resin) was stored at room temperature of 25° C. for one or more days, and then a refractive index nf of a 486.13 nm-wavelength, a refractive index nd of a 589 nm-wavelength, and a refractive index nc of a 656.27 nm-wavelength were measured respectively at 25° C. with an Abbe refractomer (DR-M2) With respect to the measured refractive indices, a difference in the refractive index of each wavelength (a refractive index of resin−a refractive index of glass, Δnf, Δnd, Δnc) of EAGLE XG™ used as the glass substrate was calculated, and from the obtained refractive index difference, an evaluation value ΔRI of the refractive index difference was further calculated.

The above evaluation results are described in table 2 shown hereafter.

TABLE 2

| | | | Breakage | | | | | | | |
|---|---|---|---|---|---|---|---|---|---|---|
| | | Bending | resistance test | | | | | | | |
| | | elastic | Characteristic | | | Sensory | Refractive index difference | | | |
| | Adhesive | modulus | value | | ΔH | test of | between substrate and resin | | | |
| | No. | (MPa) | (mm) | Remark | (%) | visibility | ΔmF | Δnd | Δnc | ΔRI |
| Embodiment 1 | 1 | 1117 | 5.0 | Glass | 0.4 | Seam | −0.0007 | −0.0018 | −0.0026 | −0.0017 |
| | | | | broken | | almost | | | | |
| | | | | | | not | | | | |
| | | | | | | seen | | | | |
| Embodiment 2 | 2 | 1216 | 5.0 | Glass | 0.6 | Seam | −0.0040 | −0.0053 | −0.0060 | −0.0051 |
| | | | | broken | | seen in | | | | |
| | | | | | | blurred | | | | |
| | | | | | | manner | | | | |
| Embodiment 3 | 3 | 4139 | 5.0 | Glass | 0.5 | Seam | −0.0038 | −0.0043 | −0.0052 | −0.0044 |
| | | | | broken | | seen in | | | | |
| | | | | | | blurred | | | | |
| | | | | | | manner | | | | |
| Embodiment 4 | 4 | 6602 | 4.5 | | 0.4 | Seam | −0.0030 | −0.0030 | −0.0032 | −0.0031 |
| | | | | | | almost | | | | |
| | | | | | | not | | | | |
| | | | | | | seen | | | | |
| Embodiment 5 | 5 | 14449 | 3.5 | | 0.4 | Seam | −0.0011 | −0.0020 | −0.0024 | −0.0018 |
| | | | | | | almost | | | | |
| | | | | | | not | | | | |
| | | | | | | seen | | | | |
| Embodiment 6 | 6 | 31496 | 2.0 | | 0.4 | Seam | −0.0014 | −0.0027 | −0.0025 | −0.0022 |
| | | | | | | almost | | | | |
| | | | | | | not | | | | |
| | | | | | | seen | | | | |
| Comparative | 7 | 37333 | 0.5 | Seam | 0.4 | Seam | 0.0008 | 0.0004 | −0.0014 | −0.0001 |
| example 1 | | | | split | | almost | | | | |
| | | | | | | not | | | | |
| | | | | | | seen | | | | |
| Comparative | 8 | 40320 | 0.5 | Seam | 1.1 | Seam | 0.0179 | 0.0177 | 0.0168 | 0.0170 |
| | | | | split | | seen | | | | |
| example 2 | | | | | | clearly | | | | |

### [Result]

As shown explicitly in table 2 above, in embodiments 1-6 using adhesive agents 1-6, the bending elastic moduli of the seam are all less than or equal to 35,500 MPa, and in the case of a breakage resistance test, resin is not split even in a 2 mm-step, and strong resistance against deformation is exhibited. Additionally, the refractive index difference ΔRI between the resin (cured materials of adhesive agents 1-6) and the substrate in a visible light region is in a range of −0.01≤ΔRI≤0.01, and the difference ΔH in the hazes of the seam and the non-seam is less than or equal to 1, and in the case of a sensory test of visibility, the seam is almost not seen or in a blurred manner, securing the seamlessness of the seam.

Meanwhile, in comparative examples 1-2 using adhesive agents 7-8, the bending elastic moduli of the seam are greater than 35,500 MPa, and in the case of a breakage resistance test, the seam is split even in a 0.5 mm-step, and resistance against deformation of the seam is very weak. Additionally, in comparative example 2, the refractive index difference ΔRI between the resin (a cured material of adhesive agent 8) and the substrate in a visible light region is 0.0170, and in the case of a sensory test of visibility, the seam is explicitly seen, securing no seamlessness of the seam.

Each of the above-described embodiments may be implemented solely, or may be combined with at least one of the embodiments partially or entirely and implemented together in one device.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. A tiling-type display device comprising:
modules, each module including:
a substrate,
a light-emitting element disposed on the substrate, and
an electrode that supplies a voltage to the light-emitting element,
wherein a seam between the modules adjacent to each other includes:
resin,
a difference ΔRI between a refractive index of the substrate and a refractive index of the resin in a visible light region is in a range of −0.01≤ΔRI≤0.01, and
a bending elastic modulus of the seam is less than or equal to 35,500 MPa.

2. The tiling-type display device of claim 1, wherein the resin includes a cured material of an adhesive composition including an epoxy compound.

3. The tiling-type display device of claim 2, wherein the epoxy compound includes an epoxy compound of epoxy equivalent weight greater than or equal to 250 g/eq.

4. The tiling-type display device of claim 3, wherein content of the epoxy compound of epoxy equivalent weight greater than or equal to 250 g/eq. is greater than or equal to 10 mass %, with respect to total mass of the adhesive composition.

5. The tiling-type display device of claim 3, wherein the epoxy compound of epoxy equivalent weight greater than or equal to 250 g/eq. is an aliphatic acyclic epoxy compound containing no aromatic group and no cycloaliphatic group.

6. The tiling-type display device of claim 3, wherein the epoxy compound of epoxy equivalent weight greater than or equal to 250 g/eq. has an aliphatic acyclic ether structure.

7. The tiling-type display device of claim 3, wherein the epoxy compound of epoxy equivalent weight greater than or equal to 250 g/eq. is a poly propylene glycol diglycidyl ether.

8. The tiling-type display device of claim 1, wherein a difference ΔRI between a refractive index of the substrate and a refractive index of the resin in a visible light region is −0.005≤ΔRI≤0.005.

9. The tiling-type display device of claim 1, wherein the tiling-type display device is a transmissive device.

10. The tiling-type display device of claim 1, wherein the difference ΔRI is obtained by measuring refractive indices nd, nf, and nc with respect to wavelengths of sodium D-line (589 nm), hydrogen F-line (486.13 nm) and hydrogen C-line (656.27 nm) of the substrate and the resin by using Abbe's refractomer.

11. The tiling-type display device of claim 1, wherein the bending elastic modulus of the seam is less than or equal to 17,000 MPa.
